(19) United States
(12) Patent Application Publication
(10) Pub. No.: US 2020/0152532 A1
(43) Pub. Date: May 14, 2020

(54) Electronic Assembly With a Component Located Between Two Substrates, and Method for Producing Same

(71) Applicant: Siemens Aktiengesellschaft, München (DE)

(72) Inventors: Rene Blank, Berlin (DE); Martin Franke, Berlin (DE); Peter Frühauf, Falkensee (DE); Rüdiger Knofe, Teltow (DE); Bernd Müller, Falkenberg (DE); Stefan Nerreter, Heidesee OT Blossin (DE); Jörg Strogies, Berlin (DE); Klaus Wilke, Berlin (DE)

(73) Assignee: Siemens Aktiengesellschaft, München (DE)

(21) Appl. No.: 16/609,580

(22) PCT Filed: Apr. 20, 2018
(86) PCT No.: PCT/EP2018/060138

§ 371 Date: Oct. 30, 2019

(30) Foreign Application Priority Data
May 2, 2017 (EP) 17169007.6

(51) Int. Cl. H01L 23/15; H01L 23/367; H01L 23/433; H01L 23/00

(52) U.S. Cl. CPC H01L 23/15; H01L 23/3675; H01L 23/4334; H01L 2224/73251; H01L 24/73; H01L 2224/32225; H01L 24/32

(57) ABSTRACT

Various embodiments include an electronic assembly comprising: a first substrate; a second substrate; and a component located between the first substrate and the second substrate. The component is in contact with the first substrate and the second substrate. A gap between the first substrate and the component is bridged with an auxiliary joining material. The first substrate defines a through-hole opening into the gap and sealed by the auxiliary joining material. The first substrate and the second substrate define a cavity closed against the environment.

### CROSS-REFERENCE TO RELATED APPLICATIONS

This application is a U.S. National Stage Application of International Application No. PCT/EP2018/060138 filed Apr. 20, 2018, which designates the United States of America, and claims priority to EP Application No. 17169007.6 filed May 2, 2017, the contents of which are hereby incorporated by reference in their entirety.

### TECHNICAL FIELD

The present disclosure relates to electronic assemblies. Various embodiments may include components located between a first substrate and a second substrate. In this regard the component is in contact with the first substrate and the second substrate.

### BACKGROUND

An electronic component in the form of a power semiconductor held between two substrates, is described in DE 10 2014 206 601 A1 and DE 10 2014 206 606 A1 for example. In the case of two-sided bonding of components such as for example power electronics chips (also referred to as bare dies) in cavities that are formed by two substrates, such as for example circuit carriers, the mounting height of the cavity has to be adapted to the thickness of the components. This gives rise to a series of tolerances, in particular if multiple components are arranged between the substrates, or the substrates themselves are connected directly to each other.

If the cavity is to be inserted into one of the substrates, for example a circuit board, made from a glass fiber resin composite material, then tolerances already arise during production of the said cavity. Additionally, the components also have different heights due to tolerances. Consequently, tolerances of more than 100 μm can arise during processing of the said components. These tolerances cannot easily be compensated for with the compensating capacity of normal sinter or solder connections.

As a result, there can be instances for example where a solder material streams sideways out of the solder connection in the case of an excessively small gap, or not enough solder material is present in the gap in the case of an excessively large gap. Both impact negatively on the thermal and electrical conductivity of the connection that is formed. To counteract this, the depth of each cavity and the height of each component can be measured in order to adapt the solder deposit individually to the tolerances present. In this method however, two additional process steps would be imposed, specifically the measuring and the individual solder dosing, which would mean additional fabrication costs.

Another option consists in providing a constructional tolerance compensation. As described in DE 10 2014 206 608 A1, one compensating method uses a hood consisting of a material capable of being heat-softened or heat-cured, that is to say a resin or a thermoplastic synthetic material, to be provided as a substrate. During joining of connections to the component or the other substrate respectively the hood can then be heated until it allows itself to be reshaped in a plastic manner, and in this way compensates for tolerances during joining. Nevertheless, the structure of this hood is relatively complex if electrical circuits are to be realized on same.

### SUMMARY

The teachings of the present disclosure describe an electronic assembly with a component located between two substrates, which can be mounted easily and in which the fabrication and mounting tolerances arising can be reliably compensated for and/or a mounting method for such an electronic assembly. For example, some embodiments include an electronic assembly with a component (11) that is located between a first substrate (12) and a second substrate (13), wherein the component is in contact with the first substrate (12) and the second substrate (13) and a gap (18) is provided between the first substrate (12) and the component, which gap is bridged with an auxiliary joining material (24), the first substrate (12) has a through-hole (21), which opens into the gap (18) and is sealed by the auxiliary joining material (24), characterized in that the first substrate (13) and the second substrate (18) give form to a cavity (16) that is closed against the environment.

In some embodiments, the first substrate (12) or the second substrate (13) consists of a ceramic.

In some embodiments, the first substrate (12) or the second substrate (13) consists of a printed circuit board.

In some embodiments, the first substrate (12) or the second substrate (13) consists of a heat sink.

In some embodiments, the component (11) is a semiconductor chip.

In some embodiments, the walls of the through-hole (21) are coated with a metal layer (23).

In some embodiments, the metal layer (23) is led out around the edge of the through-hole on to an outer side (22) of the first substrate (12) located opposite the gap (18).

In some embodiments, the through-hole (21) is sealed on the outside with an electrical insulating material (25) As another example, some embodiments include a method for manufacturing an electronic assembly, in which a component (11) is mounted between a first substrate (12) and a second substrate (13), wherein the component is bonded on the second substrate (13) and a gap (18) situated between the first substrate (12) and the component is bridged with an auxiliary joining material (24), characterized in that the first substrate (12) has a through-hole (21), which opens into the gap (18) and through which the auxiliary joining material (24) is filled into the gap (18).

In some embodiments, the auxiliary joining material (24) is dosed by making use of the capillary effect in the gap.

In some embodiments, the dosing takes place by means of dispensing.

In some embodiments, the dosing takes place by means of selective wave soldering.

In some embodiments, after the gap (18) is filled with the auxiliary joining material (24) the through-hole (21) is sealed on the outside with an electrical insulating material (25).

### BRIEF DESCRIPTION OF THE DRAWINGS

Further details of the teachings herein are described below with reference to the drawings. Identical or corresponding drawing elements are labeled with the same reference symbols in each case and are only explained multiple times to the extent that differences arise between the individual figures. In the drawings:

FIGS. 1 and 2 show exemplary embodiments of an assembly incorporating the teachings herein in cross-section in each case; and

FIGS. 3 and 4 show exemplary embodiments of a method incorporating teachings of the present disclosure in cross-section in a representative fabrication step.

### DETAILED DESCRIPTION

In some embodiments, the first substrate has a through-hole, which opens into the gap between the component and the first substrate and which is sealed by the auxiliary joining material. In this regard the hole can also be fully or partly filled with the auxiliary joining material. In some embodiments, the auxiliary joining material at least fills the gap. In this regard the hole is used for dosing the auxiliary joining material into the gap from outside. In some embodiments, the electronic assembly can be pre-mounted, with the component being bonded to the second substrate and as a result fixed in its position. In some embodiments, the gap is produced with a tolerance-affected gap size, which is influenced by the total of all tolerances arising. Tolerances can be created primarily in the case of the height of a cavity being formed between the first substrate and the second substrate, the height of the component, and in the case of the connection points between the component and the second circuit carrier, and also possibly in the case of a connection between the first and the second substrate. These tolerances can then be compensated for by dosing the right volume of auxiliary joining material through the through-hole from outside.

In some embodiments, a method for manufacturing the electronic assembly is employed that achieves the object stated above. In this method the auxiliary joining material is filled into the gap through the through-hole, with precisely so much auxiliary joining material being dosed that the required connection between the component and the substrate is formed. In some embodiments, the auxiliary joining material is dosed by making use of the capillary effect in the gap. As a result, the volume to be dosed is determined automatically since the auxiliary joining material cannot escape from the gap or the through-hole due to the capillary forces. The auxiliary joining material is then hardened. If this is a conductive adhesive for example, then it cures. If it is a solder material, it solidifies in the gap.

In some embodiments, dosing of the auxiliary joining material can take place by means of dispensing. In this regard the auxiliary joining material is inserted into the through-hole with a suitable dosing device and drawn into the gap by the capillary effect. In some embodiments, the dosing can take place by means of selective wave soldering. In this method the selective solder wave of molten solder material is moved toward the through-hole and the solder material is drawn through the through-hole into the gap. Then the through-hole can be sealed on the outside with an electrical insulating material to ensure electrical isolation with respect to the outside.

If the gap is to be filled with a solder material, the walls of the through-hole may be coated with a metal layer. This metal layer can be easily wetted by the solder material so that the said solder material can be easily drawn into the through-hole due to the capillary effects. The metal layer can be fashioned for example like a through-plating in printed circuit boards. Naturally the gap is also metalized, which is realized through metalization of the component on the one hand and by metalization of the substrate in the region of the gap on the other. In this way the gap can be used for forming an electrically conductive connection between the component and the substrate, it being possible for a circuit arrangement to electrically interconnect the component to be realized on the first substrate.

In some embodiments, the metal layer is led out around the edge of the through-hole on to an outer side of the first substrate located opposite the gap. This can be realized for example by forming a ring-shaped metalization around the edge of the through-hole on the outside. This is in contact with the metal layer in the through-hole. This supports the dosing of solder material into the gap and the through-hole if, for example, the outer side of the first substrate is brought into contact with a selective soldering wave.

In some embodiments, the first substrate or the second substrate consists of a ceramic. This can have a metal coating, for example with silver or copper. Additionally, this can be implemented in the form of a circuit carrier on which a power electronics circuit is realized. The ceramic enables a comparatively good heat dissipation in this regard. Furthermore, provision can be made for the first substrate or the second substrate to consist of a printed circuit board. This can be used to manufacture an opening for forming a cavity for the component. The cavity can be produced in the printed circuit board material, which may consist of a fiber-reinforced resin, at an acceptable fabrication cost. As printed circuit board material, a so-called FR4 material can be employed for example. This involves an epoxy-resin-based plastic reinforced with glass fibers, which is flame-retardant. The material is typically coated with copper, preferably with a finish of nickel/gold alloy, tin, or silver.

In some embodiments, the first substrate or the second substrate to include a heat sink. A heat sink is usually connected to the component in a highly heat-conducting manner. This can also be done in particular by the application of an auxiliary joining material.

There are some potential pairings for the first substrate and the second substrate. For example, the first substrate can be a printed circuit board and the second substrate can consist of a ceramic.

Another option consists in the first substrate being a printed circuit board and the second substrate a heat sink or vice versa, the second substrate is a printed circuit board and the first substrate a heat sink.

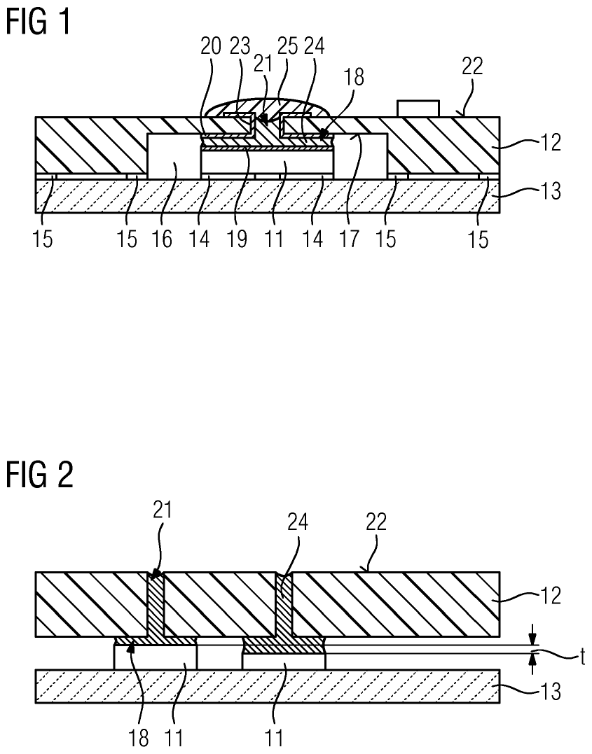

FIG. 1 represents an electronic assembly, in which a component 11, in the form of a semiconductor chip, is held between a first substrate 12, in the form of a printed circuit board, and a second substrate 13, in the form of a ceramic circuit carrier. The component 11 is electrically bonded on the second substrate 13 by using sinter connections 14. In some embodiments, the first substrate 12 and the second substrate 13 are electrically bonded directly to each other by means of solder connections 15.

A cavity 16 is formed between the first substrate 12 and the second substrate 13, which consists of a recess in the first substrate. The electronic component 11 is also located in this cavity 16. Nevertheless, a gap 18 is produced between the electronic component 11 and a floor 17 of the recess forming the cavity 16, with the said gap being lined by a metalization 19 of the component 11 and a metalization 20 of the floor 17. Additionally, a through-hole 21 opens into the gap 18, which through-hole connects an outer side 22 of the first substrate 12 to the gap 18. This through-hole 21 is lined with a metal layer 23 which also extends on to the outer side 22 of the first substrate 12 at the edge of the through-hole 21. This metal layer 23 has been produced in the form of a through-plating in the first substrate 12.

The gap 18 and the through-hole 21 are filled with the auxiliary joining material 24, where this can be a solder or a conductive adhesive. Typical solder materials comprise SnAgCu alloys, so-called SAC solders. In some embodiments, lead solders can be employed, for example SnPb or SnPbAg alloys. In some embodiments, the through-hole 21 is optionally sealed with an electrical insulating material 25 on the outer side 22, in order to ensure electrical isolation. This can be effected with a silicone substance or an epoxy-resin adhesive for example.

According to FIG. 2 a heat sink is employed as a first substrate 12 and a circuit carrier as a second substrate 13, it being possible for the circuit carrier to be in the form of a printed circuit board or in the form of a ceramic substrate. Multiple electronic components 11, which have different heights due to tolerances t, are provided on the second substrate. These constitute power semiconductors. In order to cool them, the first substrate is provided in the form of a heat sink, with the said heat sink being connected to the components 11 via the auxiliary joining material 24 (optionally the insulating material 25 is also used). FIG. 2 shows how the gaps 18, formed with different heights due to the tolerance t, are filled evenly with the auxiliary joining material. Same consists preferably of solder since solder is a good heat conductor.

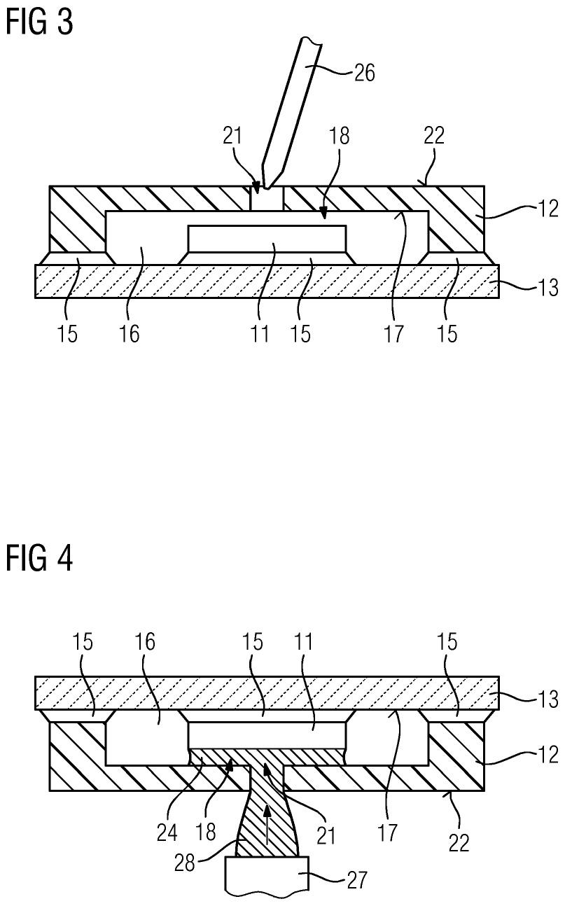

An example fabrication method for the electronic assembly can be seen in FIG. 3. In a first step the component 11, the first substrate 12, and the second substrate 13 can be combined in the position represented in FIG. 3. The assembly pieced together in this way can then pass through a reflow soldering oven in a manner not shown in detail, with the solder connections 15 being formed as diffusion soldering connections. After cooling the auxiliary joining material can be dispensed into the gap 18 by using a dosing device 26. The required volume of auxiliary joining material is determined automatically due to the capillary effect acting in the gap 18.

The assembly as shown in FIG. 4 can be pre-mounted by means of reflow soldering as described in relation to FIG. 3. The assembly is then turned over so that same is oriented with the outer side facing downward. A selective soldering head 27 is then moved toward the through-hole 21 such that a selective soldering wave 28 reaches the metal layer 23, which is not shown in detail in FIG. 4 for reasons of clarity (see FIG. 1). Due to the capillary forces acting in the through-hole 21 and in the gap 18, and the good wettability of the metal layer, the liquid solder is drawn into the gap and can then solidify there.

What is claimed is:

1. An electronic assembly comprising:
a first substrate;
a second substrate; and
a component located between the first substrate and the second substrate;
wherein the component is in contact with the first substrate and the second substrate; and
a gap between the first substrate and the component is bridged with an auxiliary joining material;
the first substrate defines a through-hole opening into the gap and sealed by the auxiliary joining material;
the first substrate and the second substrate define a cavity closed against the environment.

2. The assembly as claimed in claim, wherein at least one of the first substrate and the second substrate comprises a ceramic.

3. The assembly as claimed in claim 1, wherein at least one of the first substrate and the second substrate comprises a printed circuit board.

4. The assembly as claimed in claim 1, wherein at least one of the first substrate and the second substrate comprises a heat sink.

5. The assembly as claimed in claim 1, wherein the component comprises a semiconductor chip.

6. The assembly as claimed in claim 1, wherein walls of the through-hole are coated with a metal layer.

7. The assembly as claimed in claim 6, wherein the metal layer extends around an edge of the through-hole on to an outer side of the first substrate located opposite the gap.

8. The assembly as claimed in claim 1, wherein the through-hole is sealed on an outside opposite the gap with an electrical insulating material.

9. A method for manufacturing an electronic assembly, the method comprising:
mounting a component between a first substrate and a second substrate;
bonding the component on the second substrate; and
bridging a gap situated between the first substrate and the component with an auxiliary joining material;
wherein the first substrate has a through-hole opening into the gap; and
the auxiliary joining material is filled into the gap through the through-hole.

10. The method as claimed in claim 9, further comprising dosing the auxiliary joining material using a capillary effect in the gap.

11. The method as claimed in claim 10, wherein dosing the auxiliary joining material includes dispensing.

12. The method as claimed in claim 10, wherein dosing the auxiliary joining material includes selective wave soldering.

13. The method as claimed in claim 9, further comprising, after the gap is filled with the auxiliary joining material, sealing the through-hole from the outside with an electrical insulating material.
